(19) United States
(12) Patent Application Publication
(10) Pub. No.: US 2021/0194160 A1
(43) Pub. Date: Jun. 24, 2021

(54) WIRELESS TRANSMISSION DEVICE

(71) Applicants: BENQ CORPORATION, Taipei (TW); BenQ Intelligent Technology (Shanghai) Co., Ltd, Shanghai (CN)

(72) Inventor: Chin-Fu CHIANG, New Taipei City (TW)

(73) Assignees: BENQ CORPORATION, Taipei (TW); BenQ Intelligent Technology (Shanghai) Co., Ltd, Shanghai (CN)

(21) Appl. No.: 17/124,591

(22) Filed: Dec. 17, 2020

(30) Foreign Application Priority Data
Dec. 20, 2019 (CN) 201911321436.X

(51) Int. Cl. H01R 12/70; H01R 13/639

(52) U.S. Cl. CPC H01R 12/7023; H01R 13/639; H01R 12/7076

(57) ABSTRACT

A wireless transmission device is provided. The wireless transmission device includes a body, a connection cable electrically connected to the body, and at least one fixing member. The body includes a slot and a first fixing base. The connection cable includes a plug and a second fixing base. The plug matches the slot, and the second fixing base and the first fixing base are opposite to each other in a vertical manner. The at least one fixing member is inserted into the first fixing base and the second fixing base to fix the plug in the slot. The present invention increases the coupling stability between the body and the connection cable, stabilizes signal transmission, reduces maintenance cost, and provides an integrated appearance.

This application claims the benefit of People's Republic of China application Serial No. 201911321436.X, filed Dec. 20, 2019, the subject matter of which is incorporated herein by reference.

### BACKGROUND OF THE INVENTION

### Field of the Invention

The invention relates in general to a transmission device, and more particularly to a wireless transmission device.

### Description of the Related Art

Generally speaking, a connector is used by way of plugging and unplugging. However, when the connector is repeatedly plugged and unplugged over a long period of time, the connection cable may be bent or deflected, the connection point may become loose, and the quality of signal transmission may deteriorate.

### SUMMARY OF THE INVENTION

The invention is directed to a wireless transmission device capable of securely fixing the connection cable on the body, not only complying with the integrated design and fixing an additional connection cable but further advantageously providing an integrated appearance, stabilizing signal transmission and reducing maintenance cost.

According to a first aspect of the present invention, a wireless transmission device is provided. The wireless transmission device includes a body, a connection cable electrically connected to the body, and at least one fixing member. The body includes a slot and a first fixing base. The connection cable includes a plug and a second fixing base. The plug matches the slot, and the second fixing base and the first fixing base are opposite to each other in a vertical manner. The at least one fixing member is inserted into the first fixing base and the second fixing base to fix the plug in the slot.

Through the design that the shape of the plug matches that of the slot of the body, the second fixing base of the plug is fixed by the fixing member, such that the coupling stability between the body and the connection cable is increased, the signal transmission is stabilized, the maintenance cost is reduced, and an integrated appearance is provided.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic 3D diagram of a wireless transmission device according to an embodiment of the present invention.

FIG. 2 is an explosion diagram of a wireless transmission device according to an embodiment of the present invention.

FIG. 3 is an explosion diagram of the wireless transmission device of FIG. 2 viewed from another view angle.

FIG. 4 is an explosion diagram of wireless transmission device according to an embodiment of the present invention.

FIG. 5 is an explosion diagram of the wireless transmission device of FIG. 4 viewed from another view angle.

FIG. 6 is an interior perspective diagram of a wireless transmission device according to an embodiment of the present invention.

### DETAILED DESCRIPTION OF THE INVENTION

Detailed descriptions of the invention are disclosed below with a number of embodiments. However, the disclosed embodiments are for explanatory and exemplary purposes only, not for limiting the scope of protection of the invention. Similar/identical designations are used to indicate similar/identical elements.

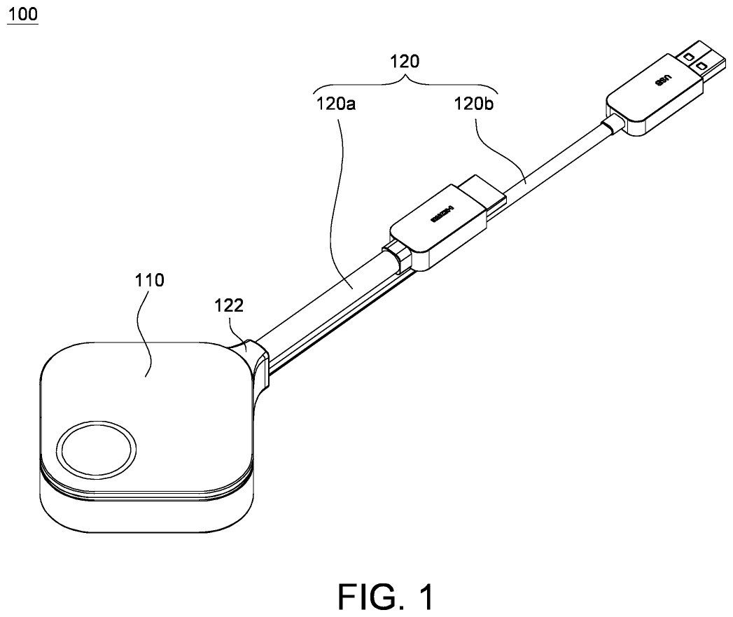

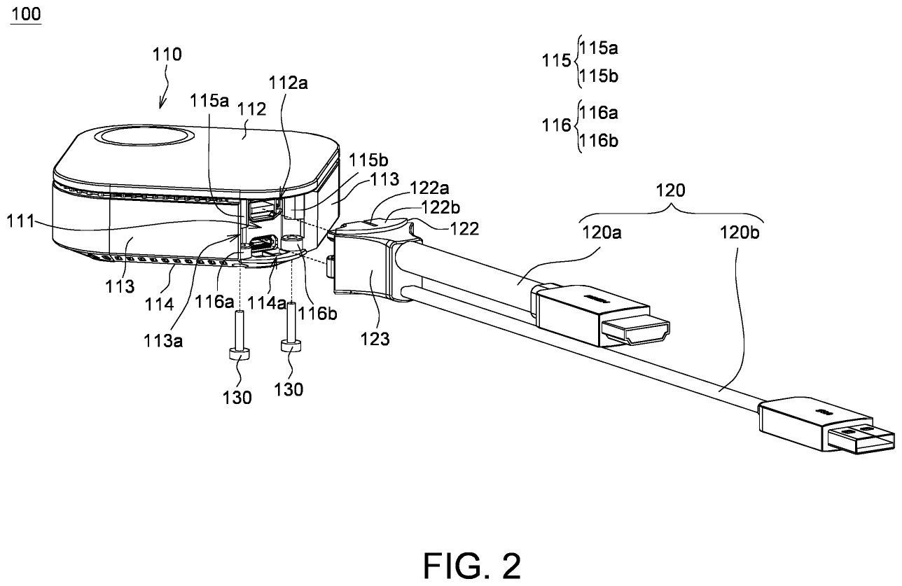

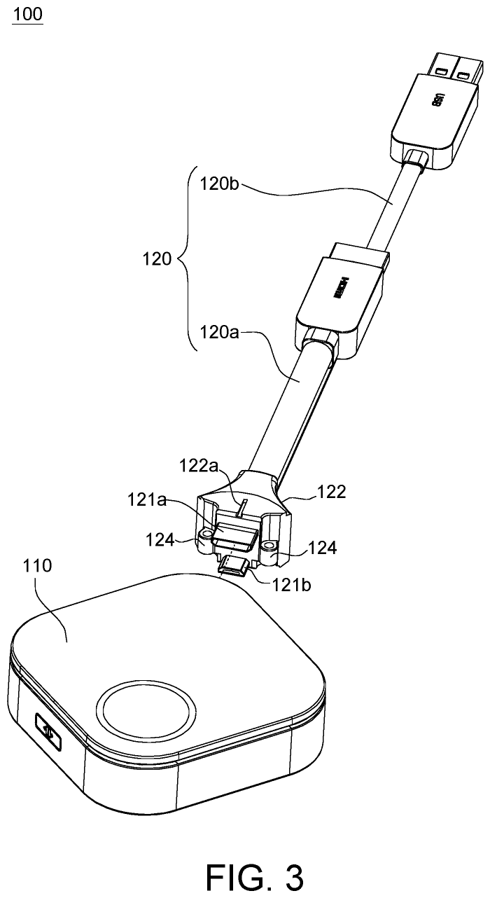

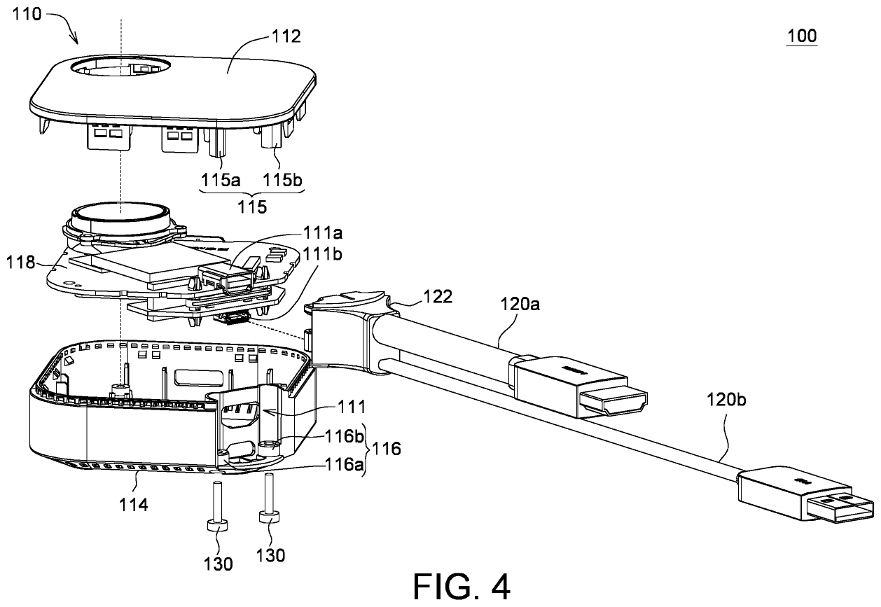

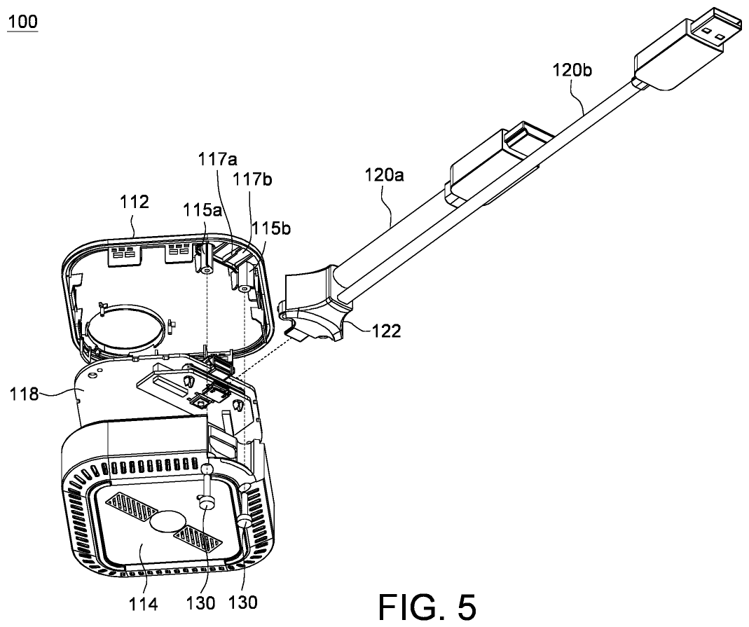

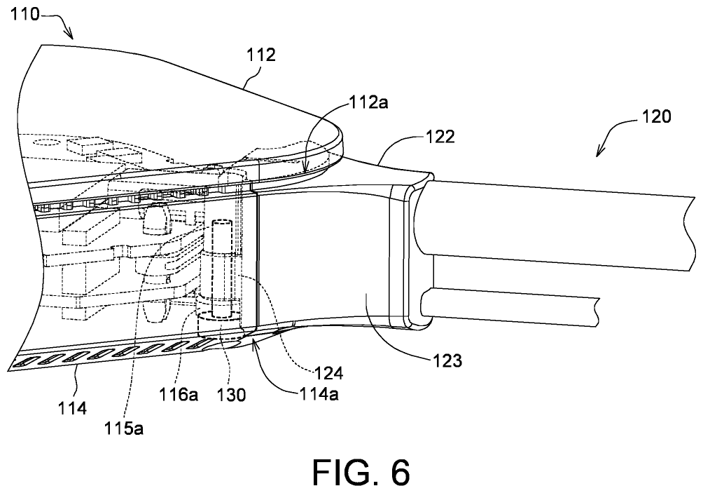

FIG. 1 is a schematic 3D diagram of a wireless transmission device 100 according to an embodiment of the present invention. FIG. 2, FIG. 3, FIG. 4 and FIG. 5 are respectively explosion diagrams of the wireless transmission device 100 viewed from different view angles. FIG. 6 is an interior perspective diagram of a wireless transmission device 100 according to an embodiment of the present invention.

Refer to FIG. 1 to FIG. 6. The wireless transmission device 100 includes a body 110, a connection cable 120 and at least one fixing member 130 (such as two). The body 110 includes a slot 111 (that is, female connector) and a set of first fixing bases 115 and 116. The connection cable 120, electrically connected to the body 110, includes a plug 122 (that is, male connector) and a set of second fixing bases 124, wherein the shape of the plug 122 matches the shape of the slot 111, and the set of second fixing bases 124 and the set of first fixing bases 115 and 116 are opposite to each other in a vertical manner. At least one fixing member 130 (for example two), is inserted into the set of first fixing bases 115 and 116 and the set of second fixing bases 124 to fix the plug 122 in the slot 111.

In an embodiment, the body 110 can be a transmitter module configured to transmit a video signal to a wireless projection device. That is, the transmitter module is configured to emit the video signal to the reception end of a wireless projection device or other wireless electronic device, and then the video signal is played by a projector or a screen. Or, the body 110 can be a receiver module configured to receive a video signal and then transmit the video signal to a wireless projection device or other wireless electronic device. The said arrangement is not subjected to specific restrictions in the present invention.

In an embodiment, the wireless transmission device 100 is electrically connected to a desktop electronic device (such as computer) or a portable electronic device (such as mobile phone) through the connection cable 120. The desktop electronic device and the portable electronic device can be provided with a video output terminal and a power output terminal. The connection cable 120 can be realized by an HDMI (High Definition Multimedia Interface) connection cable 120a or a USB connection cable 120b. The HDMI connection cable 120a is configured to connect the video output terminal, and the USB connection cable 120b is configured to connect the power output terminal or an external power source (such as the mains). Exemplarily but not restrictively, the connection cable 120 can also be realized by a USB type C connection cable configured to connect the video output terminal and the power output terminal.

That is, the connection cable 120 has a quantity of two, and the two connection cables respectively are connected to the plug 122, which includes a power connection terminal 121b (male connector) and a video transmission terminal 121a (male connector). The power connection terminal 121b (male connector) and the video transmission terminal 121a correspondingly connect a power connection terminal 111b (female connector) and a video transmission terminal 111a (female connector) of the body 110. Refer to FIG. 4. The power connection terminal 111b (female connector) and the video transmission terminal 111a (female connector) are disposed on the circuit board 118. Or, the connection cable 120 has a quantity of one, and the plug 122 includes a USB type C transmission terminal (male connector) correspondingly connecting the USB type C transmission terminal (female connector) of the body 110 and is disposed on the circuit board 118. When the male/female connector between the connection cable 120 and the body 110 becomes loose or has poor contact, the transmission stability of video signal will be affected. Therefore, in the present invention, the plug 122 is firmly fixed in the slot 111 through a more stable structure.

In an embodiment, the shape of the plug 122 is a triangle, a quadrilateral, a trapezoid or an arc, and the shape of the slot 111 matches any of the above shapes, such that when the plug 122 is inserted into the slot 111, the plug 122 and the slot 111 are tightly engaged (that is, the male connector and the female connector are tightly engaged). The shape of the body 110 is such as a quadrilateral or an arc, and the lateral side 113 of the body 110 and the lateral side 123 of the plug 122 are immediately connected to comply with the integrated design.

In an embodiment, the fixing member 130 has a quantity of two, and the two fixing members respectively are inserted into the body 110 via its bottom. The fixing member 130 may be, for example, a screw or other locking member. The bottom of the body 110 is correspondingly provided with two openings (referring to FIG. 5). The fixing member 130, once installed, is hidden at the bottom of the body 110 and will not be exposed on the outer surface of the plug 122. Therefore, when the wireless transmission device 100 needs to be repaired or the connection cable 120 needs to be replaced, the user only needs to open the fixing member 130 and unplug the connection cable 120 without having to detach the upper cover 112 of the body 110, hence making the following maintenance more convenient and the maintenance cost lowered.

Moreover, the set of first fixing bases 115 and 116 and the set of second fixing bases 124 respectively have a quantity of two, and the two first fixing bases 115 and 116 and the two second fixing bases 124 respectively are disposed on two opposite sides of the slot 111 and the plug 122 (in a vertical direction). When the fixing members 130 are inserted into the body 110 via its bottom, the fixing members 130 are inserted into the two first fixing bases 115 and 116 and the two second fixing bases 124 respectively to fix the plug 122 in the slot 111 as indicated in FIG. 6.

Additionally, to firmly fix the plug 122 in the slot 111, the set of first fixing bases 115 and 116 disposed in the slot 111 of the body 110 and the set of second fixing bases 124 disposed in the plug 122 are opposite to each other in a vertical manner, and the set of second fixing bases 124 is clamped and positioned in a vertical direction, such that after the body 110 and the connection cable 120 are coupled together, the coupling stability can be increased and signal transmission can be stabilized. Or, the upper cover 112 and the lower cover 114 of the body 110 are protruded outwards to define a limiting space, wherein the upper surface and the lower surface of the plug 122 correspondingly contact the upper cover 112 and the lower cover 114 of the body 110, such that after the body 110 and the connection cable 120 are coupled together, the coupling stability can be increased and signal transmission can be stabilized.

Refer to FIG. 4 and FIG. 5. The body 110 includes an upper cover 112, a lower cover 114 and two opposite sidewalls 113a, and the opening of the slot 111 is defined by the upper cover 112, the lower cover 114 and two opposite sidewalls 113a indented between the upper cover 112 and the lower cover 114. That is, the upper cover 112 and the lower cover 114 of the body 110 are protruded outwards to form a limiting space (that is, the slot 111). Therefore, when the plug 122 is inserted into the slot 111 between the upper cover 112 and the lower cover 114, the plug 122 is limited and positioned by two opposite inner lateral sides 112a and 114a of the upper cover 112 and the lower cover 114 to increase the coupling stability as indicated in FIG. 6.

In an embodiment, at least one of the inner lateral sides 112a and 114a of the upper cover 112 and the lower cover 114 is provided with a positioning slot 117b (referring to FIG. 5), and the upper surface or the lower surface of the plug 122 is correspondingly provided with a positioning block 122b (referring to FIG. 2) engaged with the positioning slot 117b. In another embodiment, at least one of the inner lateral sides 112a and 114a of the upper cover 112 and the lower cover 114 is provided with the positioning block 117a (referring to FIG. 5), and the upper surface or the lower surface of the plug 122 is correspondingly provided with the positioning slot 122a (referring to FIG. 2) engaged with the positioning block 117a. Thus, through the engagement between the positioning slot 122a (117b) and the positioning block 117a (122b), the plug 122 is firmly fixed in the slot 111 to increase the coupling stability.

Moreover, the upper cover 112 has a set of first slots 115a and 115b, the lower cover 114 has a set of second slots 116a and 116b, the first slots 115a and 115b and the corresponding second slots 116a and 116b are vertically aligned in a vertical direction, and a set of second fixing bases 124 is inserted into the space between the set of first slots 115a and 115b and the set of second slots 116a and 116b. The first slots 115a and 115b together with the second slots 116a and 116b form the set of first fixing bases 115 and 116 (referring to FIG. 2) opposite to the set of second fixing bases 124 in a vertical manner. That is, through the design that the second fixing base 124 is seamlessly inserted into the space between the set of first slots 115a and 115b and the set of second slots 116a and 116b, the set of second fixing bases 124 is positioned between the set of first slots 115a and 115b and the set of second slots 116a and 116b to increase the coupling stability.

The wireless transmission device disclosed in above embodiments of the present invention is capable of firmly fixing the connection cable on the body, not only complying with the integrated design and fixing an additional connection cable but further advantageously providing an integrated appearance, stabilizing signal transmission and reducing maintenance cost.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A wireless transmission device, comprising:
a body, comprising a slot and a first fixing base;
a connection cable electrically connected to the body, wherein the connection cable comprises a plug and a second fixing base, the plug matches the slot, and the second fixing base and the first fixing base are opposite to each other in a vertical manner; and
at least one fixing member inserted into the first fixing base and the second fixing base to fix the plug in the slot.

2. The wireless transmission device according to claim 1, wherein the fixing member has a quantity of two, and the two fixing members respectively are inserted into the body via a bottom of the body.

3. The wireless transmission device according to claim 1, wherein the first fixing base and the second fixing base respectively have a quantity of two, and the two first fixing bases and the two second fixing bases respectively are located on two opposite sides of the slot and the plug.

4. The wireless transmission device according to claim 1, wherein the body comprises an upper cover, a lower cover and two opposite sidewalls, and an opening of the slot is defined by the upper cover, the lower cover and the two opposite sidewalls indented between the upper cover and the lower cover.

5. The wireless transmission device according to claim 4, wherein the first fixing base comprises a set of first slots located on the upper cover and a set of second slots located on the lower cover, the set of first slots and the set of second slots are vertically aligned, and the second fixing base is respectively inserted into a space between the set of first slots and the set of second slots.

6. The wireless transmission device according to claim 5, wherein the second fixing base is seamlessly inserted into the space between the set of first slots and the set of second slots, such that the second fixing base is positioned between the set of first slots and the set of second slots.

7. The wireless transmission device according to claim 4, wherein the plug is inserted into the slot between the upper cover and the lower cover, and the plug is limited and positioned by two opposite inner lateral sides of the upper cover and the lower cover.

8. The wireless transmission device according to claim 7, wherein at least one of the inner lateral sides of the upper cover and the lower cover is provided with a positioning slot, and an upper surface or a lower surface of the plug is correspondingly provided with a positioning block engaged with the positioning slot; or, at least one of the inner lateral sides of the upper cover and the lower cover is provided with the positioning block, and the upper surface or the lower surface of the plug is correspondingly provided with the positioning slot engaged with the positioning block.

9. The wireless transmission device according to claim 1, wherein the connection cable has a quantity of two, and the two connection cables are connected to the plug, and the plug comprises a power connection terminal and a video transmission terminal; or, the connection cable has a quantity of one, and the plug comprises a USB type C transmission terminal.

10. The wireless transmission device according to claim 1, wherein the plug is shaped by a triangle, a quadrilateral, a trapezoid or an arc, and matches a shape of the slot.

11. A wireless transmission device, comprising:
a transmitter module, comprising a slot and a first fixing base;
a connection cable electrically connected to the transmitter module, wherein the connection cable comprises a plug and a second fixing base, the plug matches the slot, and the second fixing base and the first fixing base are opposite to each other in a vertical manner; and
at least one fixing member inserted into the first fixing base and the second fixing base to fix the plug in the slot.

12. The wireless transmission device according to claim 10, wherein the transmitter module is configured to transmit a video signal to a wireless projection device.

13. The wireless transmission device according to claim 10, wherein the plug comprises a power connection terminal and a video transmission terminal.

14. The wireless transmission device according to claim 10, wherein the plug comprises a USB type C transmission terminal.

15. The wireless transmission device according to claim 10, wherein the second fixing base is clamped and positioned by two of the first fixing base in a vertical direction.

16. The wireless transmission device according to claim 10, wherein an upper surface and a lower surface of the plug are correspondingly positioned when contacting an upper cover and a lower cover of the transmitter module.

17. The wireless transmission device according to claim 16, wherein the upper surface and the lower surface of the plug are provided with a positioning slot or a positioning block.

18. The wireless transmission device according to claim 16, wherein the upper cover and the lower cover of the transmitter module are provided with a positioning slot or a positioning block.

19. A wireless transmission device, comprising:
a receiver module, comprising a slot and a first fixing base;
a connection cable electrically connected to the receiver module, wherein the connection cable comprises a plug and a second fixing base, the plug matches the slot, and the second fixing base and the first fixing base are opposite to each other in a vertical manner; and
at least one fixing member inserted into the first fixing base and the second fixing base to fix the plug in the slot.

20. The wireless transmission device according to claim 19, wherein the receiver module is configured to receive and transmit a video signal to a wireless projection device.
